(19) United States
(12) Patent Application Publication
(10) Pub. No.: US 2025/0331068 A1
(43) Pub. Date: Oct. 23, 2025

(54) HEATER WITH EXTERNAL OUTER ZONE THERMOCOUPLE CHANNEL THROUGH HEATER SHAFT

(71) Applicant: Applied Materials, Inc., Santa Clara, CA (US)

(72) Inventors: Jian LI, Fremont, CA (US); Ankit Atul GORATELA, San Jose, CA (US); Ajith KARONNAN RAMAPURATH, Bangalore (IN); Ravi SIMHA, Bangalore (IN); Devarshi VYAS, Bangalore (IN); Juan Carlos ROCHA-ALVAREZ, San Carlos, CA (US)

(21) Appl. No.: 19/174,001

(22) Filed: Apr. 9, 2025

(30) Foreign Application Priority Data
Apr. 23, 2024 (IN) 202441032021

(51) Int. Cl. H05B 3/24; G01K 1/14; G01K 7/02; H01L 21/67; H01L 21/683; H05B 3/06

(52) U.S. Cl. CPC H05B 3/24; G01K 1/14; G01K 7/02; H01L 21/67248; H01L 21/6833; H05B 3/06; H05B 2203/017

(57) ABSTRACT

Embodiments of the present disclosure provide a system and method for constructing a heater assembly. The method includes forming a groove on a bottom surface of a heater plate, forming an opening through a sidewall of a heater shaft, bonding the heater shaft to the heater plate such that the opening through the sidewall of the heater shaft cooperates with the groove of the bottom surface of the heater plate to define a channel, and inserting a thermocouple into the opening formed through the sidewall of the heater shaft and into the groove of the heater plate.

### BACKGROUND

### Field

Embodiments described herein generally relate to an apparatus and method used in the manufacture of semiconductor devices. More specifically, embodiments described herein relate to constructing a ceramic heater including a heater plate and a heater shaft assembled to receive a thermocouple.

### Description of the Related Art

Substrate support pedestals are widely used to support substrates within semiconductor processing systems during substrate processing. The substrate support pedestals generally include an electrostatic chuck bonded to a cooling base with a bond layer. An electrostatic chuck generally includes one or more embedded electrodes which are driven to an electrical potential to hold a substrate against the electrostatic chuck during processing. The cooling base typically includes one or more cooling channels and aids in controlling the temperature of the substrate during processing. Further, the electrostatic chuck may include one or more gas flow passages that allow a gas to flow between the electrostatic chuck and the substrate to assist in controlling the temperature of the substrate during process. The gas fills the area between the electrostatic chuck and the substrate. However, constructing the body of the electrostatic chuck to accommodate a thermocouple can be expensive. The heater plate includes a top plate and bottom plate with respective channels, where the top plate is bonded to the bottom plate using diffusion bonding. After the heater plate is formed using diffusion bonding, the heater plate is bonded to a heater shaft using diffusion bonding. As such, this process results in applying diffusion bonding twice, thus increasing the cost of manufacture of semiconductor devices.

Accordingly, what is needed in the art are improved methods and structures to form a ceramic heater.

### SUMMARY

Embodiments of the present disclosure provide a method including forming a groove on a bottom surface of a heater plate, forming an opening through a sidewall of a heater shaft, bonding the heater shaft to the heater plate such that the opening through the sidewall of the heater shaft cooperates with the groove of the bottom surface of the heater plate to define a channel, and inserting a thermocouple into the opening formed through the sidewall of the heater shaft and into the groove of the heater plate.

Embodiments of the present disclosure provide a heater assembly including a heater plate defining a groove on a bottom surface thereof and a heater shaft defining an opening through a sidewall thereof. The heater shaft is bonded to the heater plate such that the opening through the sidewall of the heater shaft cooperates with the groove of the bottom surface of the heater plate to define a channel.

Embodiments of the present disclosure provide a method including constructing a heater plate with a surface notch, constructing a heater shaft having an opening extending through a sidewall thereof, and assembling the heater shaft to the heater plate such that the opening extending through the sidewall of the heater shaft cooperates with the surface notch of the heater plate to define a channel to receive a thermocouple therethrough.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic for forming a channel in a ceramic heater by diffusion bonding.

FIG. 2 is a schematic where a channel is formed through a heater shaft bonded to a heater plate defining a groove, according to one or more of the embodiments described herein.

FIG. 3 is a schematic where the heater shaft is diffusion bonded to the heater plate and connection rods are coupled to elements of the heater plate, according to one or more of the embodiments described herein.

FIG. 4 is a schematic where a thermocouple is inserted through the channel defined in the heater shaft to extend to the distal end of the groove of the heater plate, according to one or more of the embodiments described herein.

FIG. 5 is a method for forming a ceramic heater including a heater plate and a heater shaft to receive a thermocouple, according to one or more of the embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to methods and systems for cost-effectively constructing a heater assembly or ceramic heater including a heater plate and a heater shaft for receiving at least one thermocouple.

The fabrication of microelectronic devices typically involves a complicated process sequence requiring hundreds of individual processes performed on semi-conductive, dielectric, and conductive substrates. Examples of these processes include oxidation, diffusion, ion implantation, thin film deposition, cleaning, etching, and lithography, among other operations. Each operation is time consuming and expensive.

With ever-decreasing critical dimensions for microelectronic devices, the design and fabrication for these devices on substrates is becoming or has become increasingly complex. Control of the critical dimensions and process uniformity becomes increasingly more significant. Complex multilayer stacks used to make microelectronic devices involve precise process monitoring of the critical dimensions for the thickness, roughness, stress, density, and potential defects. Process recipes for forming the devices have multiple incremental processes to ensure critical dimensions are maintained. Typically, each incremental process may utilize one or more processing chambers that adds additional time for forming the devices and also increases opportunities for forming defects.

In general, an electrostatic chuck assembly has an edge ring resting on a ceramic plate. The ceramic plate supports a substrate during plasma processing. The ceramic plate has one or more heaters therein that can heat the substrate up to, for example, 700 degrees C. The ceramic plate includes a pair of chucking electrodes for chucking the substrate. An edge electrode is extended to nearly the very edge of the ceramic plate, and can be powered by an alternating current (AC) power supply for tuning the plasma adjacent the edge of the substrate. This includes, for example, to create a plasma sheath at the substrate edge more similar to that over more central regions of the substrate, hence reducing non-uniform processing adjacent to the substrate edge compared to the rest of the substrate. As a result, the available real estate on the substrate for productive manufacture of a semiconductor devices can be increased. By better control of the plasma at the circumferential outer region of the substrate, control of the film profile across the full surface of the substrate can be maintained while operating at frequencies from 350 kHz to 60 MHz. The ceramic plate enables AC, such as radio frequency (RF), pulsing therein at very low duty cycles with a pulsing frequency between 0.2 Hz to 20 Hz to prevent film damage by enabling bottom-up trench fill. The low duty cycle AC pulsing at the 0.2 Hz to 20 Hz level, can be utilized for plasma enhanced chemical vapor deposition (PECVD) and plasma enhanced atomic layer deposition (PEALD) processes which enable bottom-up filling of trenches by preventing the sidewalls of the trenches from closing in during the fill, which deters porous film formation in the trenches.

An embedded ground electrode helps to prevent AC coupling to the chamber bottom, thereby reducing required chamber depth, and thus, the chamber volume. The reduced chamber volume beneficially reduces the purge time required during a PEALD process. Advantageously, the high temperature electrostatic chuck assembly can perform both PECVD/PEALD deposition as well as in-situ etch/treatment processes all while using the same ceramic plate. The electrostatic chuck assembly enables improved film coverage at the outer circumferential portion of the substrate by using the edge electrode.

However, an electrostatic chuck assembly or ceramic heater can be expensive to manufacture, especially when manufactured to accommodate a channel for receiving a thermocouple. In a typical configuration, a top plate and a bottom plate with respective channels are separately constructed. The top plate is then bonded to the bottom plate using diffusion bonding. After the heater plate is formed using diffusion bonding (i.e., bonding the top plate to the bottom plate), the heater plate is then bonded to a heater shaft using diffusion bonding. As such, this process results in applying diffusion bonding twice, thus increasing the cost of manufacture of semiconductor devices. The example embodiments present an improved method and system for constructing a ceramic heater with only one bonding application. In the example embodiments, a groove or notch or slot is formed on a bottom surface of a heater plate. An opening is then formed through a sidewall of a heater shaft. The heater shaft is bonded to the heater plate such that the opening through the sidewall of the heater shaft cooperates with the groove or slot of the bottom surface of the heater plate to define a channel. A thermocouple can then be inserted into the opening formed through the sidewall of the heater shaft and into the groove or slot of the heater plate. The thermocouple may extend to the distal end of the groove or slot or notch of the heater plate. The groove or notch or slot of the heater plate is sealed with a first seal and the opening extending through the sidewall of the heater shaft is sealed with a second seal.

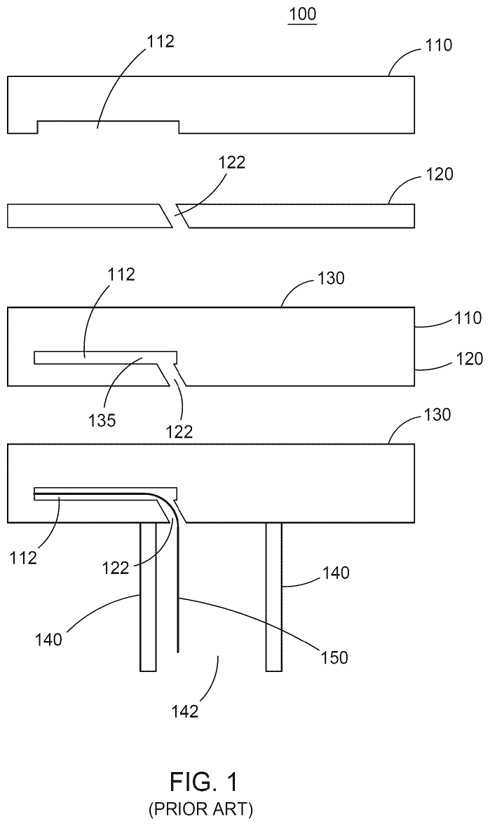

FIG. 1 is a schematic for forming a channel in a ceramic heater by diffusion bonding.

In the process 100, the ceramic heater or heater assembly is formed or constructed using a top plate 110 and a bottom plate 120. The top plate 110 has a groove 112. The groove 112 can also be referred to as a notch or slot or indent or indentation or depression. The groove 112 can be machined into the top plate 110. The bottom plate 120 has an opening 122 formed therethrough. The top plate 110 is placed over the bottom plate 120 to form a ceramic plate or heater plate 130. The top plate 110 may be formed from the same material as the bottom plate 120. The material may be, e.g., aluminum nitride (AlN). The top plate 110 is bonded to the bottom plate 120 by using diffusion bonding.

Diffusion bonding is a technique used in semiconductor manufacturing to join two surfaces together at the atomic level by promoting the diffusion of atoms across the interface. This process typically involves applying heat and pressure to the surfaces to be bonded. During diffusion bonding, atoms from each surface migrate across the interface due to thermal energy, overcoming the surface barriers and forming bonds with atoms from the opposite surface. This results in a strong and seamless bond between the two materials. In semiconductor fabrication, diffusion bonding can be used to join different semiconductor materials or to attach semiconductor devices to substrates. It is a critical process for creating integrated circuits and other semiconductor devices with complex structures and functionalities.

The diffusion bonding is applied to provide cooperation between the groove 112 of the top plate 110 and the opening 122 of the bottom plate 120. This results in a channel 135 defined by the bonding of the top plate 110 to the bottom plate 120.

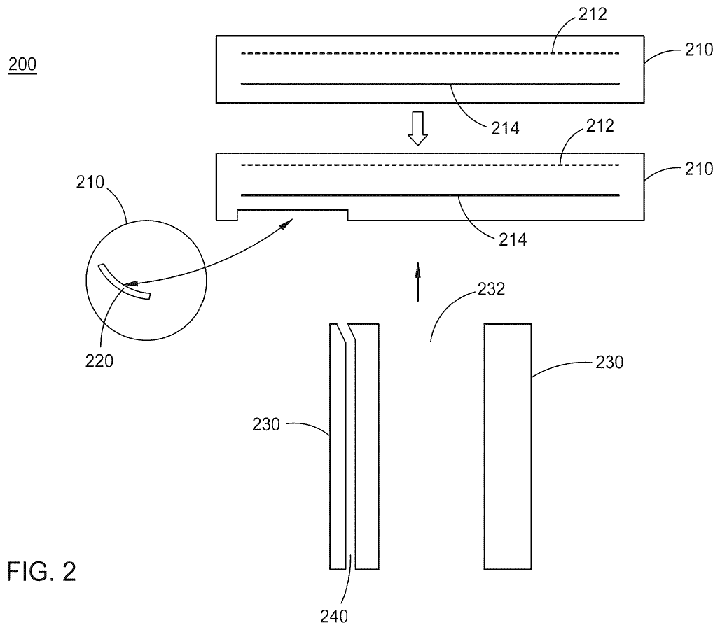

After the top plate 110 is bonded to the bottom plate 120 to define the channel 135, a heater shaft 140 is bonded to the heater plate 130 to form a ceramic heater or heater assembly. The bonding is also achieved by using diffusion bonding. The heater shaft includes a central opening or central channel 142. As such, this is a two-step bonding process. First, the top plate 110 is diffusion bonded to the bottom plate 120 to form the heater plate 130 and then the heater plate 130 is diffusion bonded to the heater shaft 140. The combination of the heater plate 130 and the heater shaft 140 defines the ceramic heater or heater assembly. Diffusion bonding can be expensive. As such, it would be beneficial to change the bonding operation from a two-step bonding operation to a one-step bonding operation, as described below with reference to FIGS. 2-5.

After the heater plate 130 is bonded to the heater shaft 140, a thermocouple 150 may be inserted into the central channel 142 of the heater shaft 140 and extended into the channel 135 defined by the heater plate 130. The thermocouple 150 may extend to a distal end or distal most end of the channel 135. The thermocouple 150 may contact the distal most end of the channel 135 (at the groove 112). The thermocouple 150 may rest and be secured at the distal most end of the channel 135.

The thermocouple 150 is a temperature sensor that consists of two different conductive metals joined together at one end. When the junction of the two metals is heated or cooled, it generates a voltage proportional to the temperature difference. This voltage can be measured and used to determine the temperature at the junction. The thermocouple 150 is used to measure the temperature on the outside region of the heater plate 130 when the heater plate 130 is inserted into a vacuum chamber (not shown).

FIG. 2 is a schematic where a channel is formed through a heater shaft bonded to a heater plate defining a groove, according to one or more of the embodiments described herein.

In the process 200, the heater plate 210 is a single piece or unit or component. The heater plate 210 includes internal electrodes 212 and a heating element 214. The heater plate 210 may be referred to as an electrostatic chuck or a substrate support.

When positive and negative voltages are applied to the internal electrodes 212 of the heater plate 210 while the workpiece is placed on the heater plate 210, the electric charges in the workpiece move so that they are attracted to the internal electrodes 212. This generates a Coulomb force between the internal electrodes 212 and the workpiece, and the workpiece is adsorbed to the heater plate 210.

The heating element 214 is suitable for controlling the temperature of a substrate (not shown) supported on an upper surface of the substrate support. The heating element 214 may be embedded in the substrate support. The substrate support is resistively heated by applying an electric current from a heater power source (not shown) to the heating element 214. The heater power source may be coupled through an RF bias impedance matching circuit (not shown). The heating element 214 may be or include a nickel-chromium wire encapsulated in a nickel-iron-chromium alloy (e.g., INCOLOY® alloy) sheath tube. The electric current supplied from the heater power source may regulated by a controller to control the heat generated by the heating element 214, thus maintaining the substrate and the substrate support at an effectively constant temperature during film deposition. The supplied electric current may be adjusted to selectively control the temperature of the substrate support to be about 50° C. to about 600° C.

A groove 220 is machined into the heater plate 210. The groove 220 can be referred to as a notch or slot or indentation or depression. The groove 220 is formed on a bottom surface of the heater plate 210. The groove 220 is formed in a non-central portion or surface of the heater plate 210. The groove 220 may have a length of 100 to 120 mm and a width of 3 to 6 mm.

After the groove 220 is formed in the heater plate 210, the heater shaft 230 is formed. An opening 240 is formed into the sidewall of the heater shaft 230. The heater shaft 230 also includes a central channel 232. The central channel 232 is parallel to the opening 240. The opening 240 extends an entire length of the heater shaft 230. The opening 240 may also be referred to as a sidewall opening.

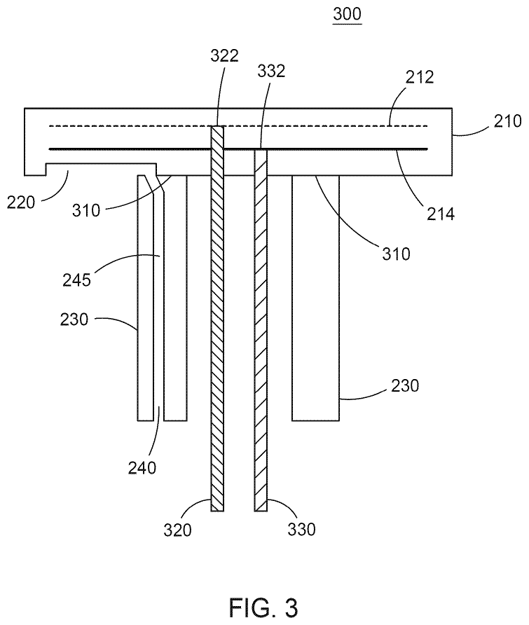

The heater shaft 230 is bonded to the heater plate 210 to define a ceramic heater or a heater assembly. The bonding applied may be diffusion bonding, as described below with reference to FIG. 3.

FIG. 3 is a schematic where the heater shaft is diffusion bonded to the heater plate and connection rods are coupled to elements of the heater plate, according to one or more of the embodiments described herein.

In the structure 300, the heater shaft 230 is bonded to the heater plate 210 such that the groove 220 of the heater plate 210 cooperates with the opening 240 of the heater shaft 230 to define a channel 245. Stated differently, the bonding 310 of the heater shaft 230 to the heater plate 210 creates a single channel 245 extending from a bottom section of the heater shaft 230 to a distal tip of the groove 220 in the heater plate 210. The combination of the heater shaft 230 and the heater plate 210 may be referred to as a heater assembly or ceramic heater.

A first connection rod 320 is coupled to the internal electrodes 212 and a second connection rod 330 is coupled to the heating element 214. The first connection rod 320 may be a heat transfer fluid connection and the second connection rod 330 may be a backpressure heat transfer gas connection. The first connection rod 320 and the second connection rod 330 are brazed to the internal electrodes 212 and the heating element 214, respectively. Brazing refers to a process used to join two metals (or one metal to a ceramic) by melting and flowing a filler metal into the joint interface, which has a lower melting point than the two workpieces. Brazing occurs at temperatures above 450°. The first connection rod 320 is brazed at a point 322 of the internal electrodes 212 and the second connection rod 330 is brazed at a point 332 of the heating element 214. The first connection rod 320 and the second connection rod 330 extend above a top surface of the groove 220. The first connection rod 320 is parallel to the second connection rod 330. The first connection rod 320 and the second connection rod 330 extend a length of the heater shaft 230.

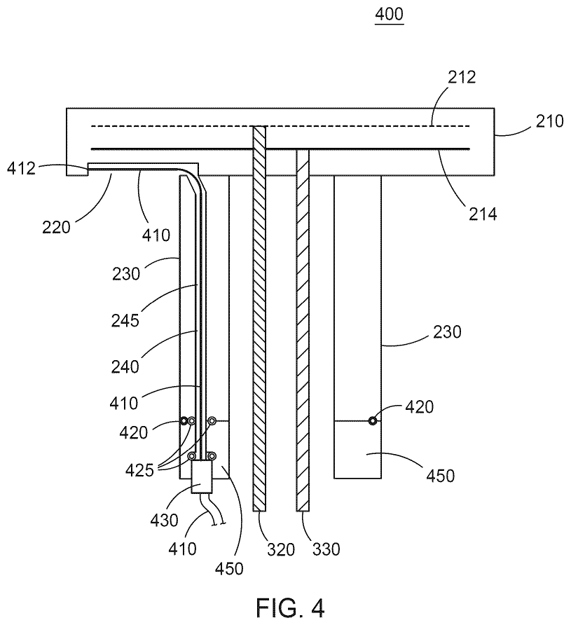

FIG. 4 is a schematic where a thermocouple is inserted through the channel defined in the heater shaft to extend to the distal end of the groove of the heater plate, according to one or more of the embodiments described herein.

In the structure 400, a thermocouple 410 may be inserted into the opening 240 of the heater shaft 230 and extend into the channel 245. The thermocouple 410 may extend to a distal end 412 of the groove 220. The groove 220 of the heater plate 210 may be sealed with a seal 420. The opening 240 of the heater shaft 230 may be sealed with at least one seal 425. The seal 420 may be an O-ring. Similarly, the at least one seal 425 may be an O-ring. In one example, the at least one seal 425 may be two O-rings. Once the thermocouple 410 is positioned or placed within the channel 245 extending within both the heater shaft 230 and the heater plate 210, the heater plate 210 may be installed in a vacuum chamber (not shown). The thermocouple 410 can be used to measure the temperature on the outside of the heater plate 210. This temperature may be referred to as an outer zone temperature. A coupler 430 may assist in creating a barrier with the atmosphere to maintain the vacuum around the heater plate 210 when the heater plate 210 is inserted within a vacuum chamber (not shown). The coupler 430 may be attached or coupled to the lower portion 450 of the heater shaft 230. The lower portion 450 of the heater shaft 230 may be, e.g., aluminum (Al). The thermocouple 410 may slide through the coupler 430.

In one example, more than one thermocouple may be inserted through the channel 245. In another example, the distal tip of the thermocouple 410 may rest and be secured at the distal most tip or distal end 412 of the groove 220. The thermocouple 410 is thus constrained at the distal end 412 of the groove 220.

In another example, the thermocouple 410 travels in a first direction in the opening 240 formed through the sidewall of the heater shaft 230 and travels in a second direction in the groove 220 on the bottom surface of the heater plate 210 such that the first direction is perpendicular to the second direction.

The structure 400 was constructed by applying only one diffusion bonding process. The diffusion bonding process was used to bond the heater plate 210 to the heater shaft 230 to define the ceramic heater or heater assembly. The heater plate 210 is constructed as a single unit piece or single unit component without the need for diffusion bonding of any of its components. As such, manufacturing costs can be significantly reduced as the construction of the ceramic heater or heater assembly (i.e., heater shaft 230 and heater plate 210) requires only one diffusion bonding process between the heater shaft 230 and heater plate 210.

An advantage of using a one-step diffusion bonding process versus a two-step diffusion bonding process is that the resulting surface area is about 22.6 times bigger. In other words, the bonding surface area is significantly reduced (by about 22.6 times) resulting in more surface area to be used for other purposes. Thus, less surface area is dedicated to bonding.

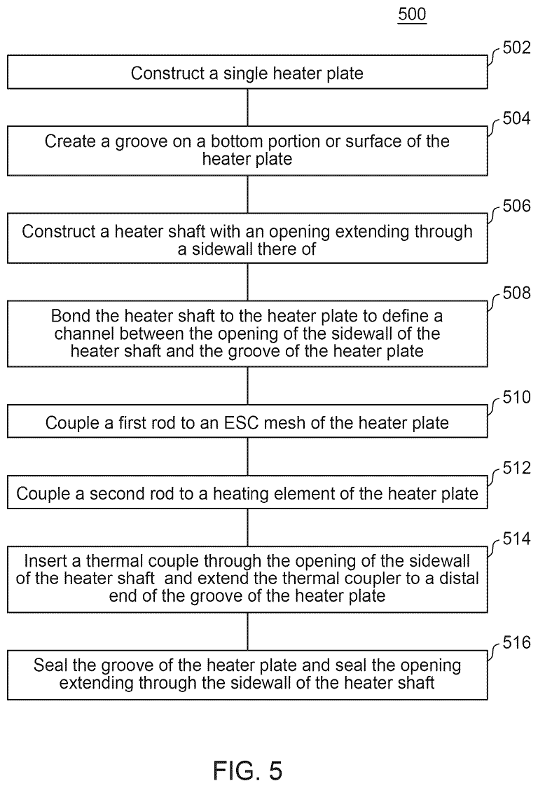

FIG. 5 is a method 500 for forming a ceramic heater including a heater plate and a heater shaft to receive a thermocouple, according to one or more of the embodiments described herein.

In block 502, a single heater plate is constructed.

In block 504, a groove or notch or slot is constructed on a bottom portion or surface of the heater plate.

In block 506, a heater shaft with an opening extending through a sidewall thereof is constructed.

In block 508, the heater shaft is bonded to the heater plate to define a channel between the opening of the sidewall of the heater shaft and the groove or notch of the heater plate.

In block 510, a first rod is coupled to an ESC mesh of the heater plate. The ESC mesh may include a pair of electrodes.

In block 512, a second rod is coupled to a heating element of the heater plate.

In block 514, a thermocouple is inserted through the opening of the heater shaft and extend the thermocouple to a distal end of the groove of the heater plate.

In block 516, the groove of the heater plate is sealed and the opening of the heater shaft extending through the sidewall thereof is also sealed. The first seal may be a single O-ring, whereas the second seal may be a pair of O-rings.

In summary, the example embodiments present an improved method and system for constructing a ceramic heater or heater assembly with only one bonding application. In the example embodiments, a groove or notch or slot is formed on a bottom surface of a heater plate. An opening is then formed through a sidewall of a heater shaft. The heater shaft is bonded to the heater plate such that the opening through the sidewall of the heater shaft cooperates with the groove of the bottom surface of the heater plate to define a channel. A thermocouple can then be inserted into the opening formed through the sidewall of the heater shaft and into the groove of the heater plate. The thermocouple may extend to the distal end of the groove or notch of the heater plate where it is secured in place. The groove or notch or slot of the heater plate is sealed with a first seal and the opening extending through the sidewall of the heater shaft is sealed with a second seal.

While this specification contains many specific implementation details, these should not be construed as limitations on the scope of what may be claimed, but rather as descriptions of features that may be specific to particular implementations. Certain features that are described in this specification in the context of separate implementations may also be implemented, in combination, in a single implementation. Conversely, various features that are described in the context of a single implementation may also be implemented in multiple implementations, separately, or in any suitable sub-combination. Moreover, although previously described features may be described as acting in certain combinations and even initially claimed as such, one or more features from a claimed combination may, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional) to achieve desirable results. In certain circumstances, multitasking or parallel processing (or a combination of multitasking and parallel processing) may be advantageous and performed as deemed appropriate. While the various steps in an embodiment method or process are presented and described sequentially, one of ordinary skill in the art will appreciate that some or all of the steps may be executed in different order, may be combined, or omitted, and some or all of the steps may be executed in parallel. The steps may be performed actively or passively. The method or process may be repeated or expanded to support multiple components or multiple users within a field environment. Accordingly, the scope should not be considered limited to the specific arrangement of steps shown in a flowchart or diagram.

Furthermore, any claimed implementation is considered to be applicable to at least a computer-implemented method; a non-transitory, computer-readable medium storing computer-readable instructions to perform the computer-implemented method; and a computer system including a computer memory interoperability coupled with a hardware processor configured to perform the computer-implemented method or the instructions stored on the non-transitory, computer-readable medium.

As used herein, “a CPU”, “controller”, “a processor”, “at least one processor”, or “one or more processors”, generally refers to a single processor configured to perform one or multiple operations or multiple processors configured to collectively perform one or more operations. In the case of multiple processors, performance the one or more operations could be divided amongst different processors, though one processor may perform multiple operations, and multiple processors could collectively perform a single operation. Similarly, “a memory”, “at least one memory”, or “one or more memories”, generally refers to a single memory configured to store data and/or instructions, multiple memories configured to collectively store data and/or instructions.

As used herein, “gas” and “fluid” may be used interchangeable with either term generally referring to elements, compounds, materials, etc., having the properties of a gas, a fluid, or both a gas and a fluid.

Unless defined otherwise, all technical and scientific terms used have the same meaning as commonly understood by one of ordinary skill in the art to which these systems, apparatuses, methods, processes and compositions belong.

In this disclosure, the terms “top”, “bottom”, “side”, “above”, “below”, “up”. “down”, “upward”, “downward,” “horizontal,” “vertical,” and the like do not refer to absolute directions. Instead, these terms refer to directions relative to a nonspecific plane of reference. This non-specific plane of reference may be vertical, horizontal, or other angular orientation.

The singular forms “a”, “an”, and “the”, include plural referents, unless the context clearly dictates otherwise. Within a claim, reference to an element in the singular is not intended to mean “one and only one” unless specifically so stated, but rather “one or more”. Unless specifically stated otherwise, the term “some” refers to one or more.

Embodiments of the present disclosure may suitably “comprise”, “consist”, or “consist essentially of”, the limiting features disclosed, and may be practiced in the absence of a limiting feature not disclosed. As used here and in the appended claims, the words “comprise”, “has”, and “include”, and all grammatical variations thereof are each intended to have an open, non-limiting meaning that does not exclude additional elements or steps.

“Optional” and “optionally” means that the subsequently described material, event, or circumstance may or may not be present or occur. The description includes instances where the material, event, or circumstance occurs and instances where it does not occur.

“Coupled” and “coupling” means that the subsequently described material is connected to previously described material. The connection may be a direct, or indirect connection, and may, or may not, include intermediary components such as plumbing, wiring, fasteners, mechanical power transmission, electrical communication, wired and/or wireless transmission, etc., which may suitable to affect operation of the components.

As used, the term “determining” encompasses a wide variety of actions. For example, “determining” may include calculating, computing, processing, deriving, investigating, looking up, for example, looking up in a table, a database, or another data structure, and ascertaining. In addition, “determining” may include receiving, for example, receiving information, and accessing, for example, accessing data in a memory. In addition, “determining” may include resolving, selecting, choosing, and establishing.

When the word “approximately” or “about” are used, this term may mean that there may be a variance in value of up to ±10%, of up to 5%, of up to 2%, of up to 1%, of up to 0.5%, of up to 0.1%, or up to 0.01%.

Ranges may be expressed as from about one particular value to about another particular value, inclusive. When such a range is expressed, it is to be understood that another embodiment is from the one particular value to the other particular value, along with all particular values and combinations thereof within the range.

As used, terms such as “first” and “second” are arbitrarily assigned and are merely intended to differentiate between two or more components of a system, an apparatus, or a composition. It is to be understood that the words “first” and “second” serve no other purpose and are not part of the name or description of the component, nor do they necessarily define a relative location or position of the component. Furthermore, it is to be understood that that the mere use of the term “first” and “second” does not require that there be any “third” component, although that possibility is envisioned under the scope of the various embodiments described.

Although only a few example embodiments have been described in detail, those skilled in the art will readily appreciate that many modifications are possible in the example embodiments without materially departing from the disclosed scope as described. Accordingly, all such modifications are intended to be included within the scope of this disclosure as defined in the following claims. In the claims, means-plus-function clauses are intended to cover the structures described as performing the recited function and not only structural equivalents, but also equivalent structures. It is the express intention of the applicant not to invoke 35 U.S.C. § 112(f), for any limitations of any of the claims, except for those in which the claim expressly uses the words ‘means for’ together with an associated function.

While the foregoing is directed to embodiments of the present disclosure, other and further embodiments of the disclosure may be devised without departing from the basic scope thereof, and the scope thereof is determined by the claims that follow.

What is claimed is:

1. A method comprising:
forming a groove on a bottom surface of a heater plate;
forming an opening through a sidewall of a heater shaft;
bonding the heater shaft to the heater plate such that the opening through the sidewall of the heater shaft cooperates with the groove of the bottom surface of the heater plate to define a channel; and
inserting a thermocouple into the opening formed through the sidewall of the heater shaft and into the groove of the heater plate.

2. The method of claim 1, wherein the heater shaft is bonded to the heater plate using diffusion bonding.

3. The method of claim 1, wherein the heater plate includes a pair of electrodes and a heating element.

4. The method of claim 3, wherein a first connecting rod is coupled to the pair of electrodes and a second connecting rod is coupled to the heating element.

5. The method of claim 1, wherein the thermocouple extends to a distal end of the groove of the heater plate.

6. The method of claim 1, wherein the groove of the heater plate is sealed with a first O-ring seal.

7. The method of claim 1, wherein the opening formed through the sidewall of the heater shaft is sealed with a second O-ring seal.

8. The method of claim 1, wherein the groove on the bottom surface of the heater plate has a length ranging from 100 to 120 mm.

9. The method of claim 1, wherein the groove on the bottom surface of the heater plate is vertically offset from a central channel defined by the heater shaft.

10. The method of claim 1, wherein the thermocouple travels in a first direction in the opening formed through the sidewall of the heater shaft and travels in a second direction in the groove on the bottom surface of the heater plate such that the first direction is perpendicular to the second direction.

11. The method of claim 1, wherein the heater shaft and the heater plate define a heater assembly.

12. A heater assembly comprising:
a heater plate defining a groove on a bottom surface thereof; and
a heater shaft defining an opening through a sidewall thereof,
wherein the heater shaft is bonded to the heater plate such that the opening through the sidewall of the heater shaft cooperates with the groove of the bottom surface of the heater plate to define a channel.

13. The heater assembly of claim 11, wherein a thermocouple extends into the opening formed through the sidewall of the heater shaft and into the groove of the heater plate.

14. The heater assembly of claim 11, wherein the heater plate includes a pair of electrodes and a heating element.

15. The heater assembly of claim 14, wherein a first connecting rod is coupled to the pair of electrodes and a second connecting rod is coupled to the heating element.

16. The heater assembly of claim 11, wherein a first O-ring seal is used to seal the groove of the heater plate.

17. The heater assembly of claim 11, wherein a second O-ring seal is used to seal the opening formed through the sidewall of the heater shaft.

18. The heater assembly of claim 11, wherein the groove on the bottom surface of the heater plate has a length ranging from 100 to 120 mm.

19. A method comprising:
constructing a heater plate with a surface notch;
constructing a heater shaft having an opening extending through a sidewall thereof; and
assembling the heater shaft to the heater plate such that the opening extending through the sidewall of the heater shaft cooperates with the surface notch of the heater plate to define a channel to receive a thermocouple therethrough.

20. The method of claim 19, wherein the surface notch of the heater plate is sealed with a first O-ring seal and the opening extending through the sidewall of the heater shaft is sealed with a second O-ring seal.
